(19) United States
(12) Patent Application Publication
(10) Pub. No.: US 2024/0321943 A1
(43) Pub. Date: Sep. 26, 2024

(54) SEMICONDUCTOR MEMORY DEVICE

(71) Applicant: SAMSUNG ELECTRONICS CO., LTD., SUWON-SI (KR)

(72) Inventors: Jungmin Park, Suwon-si (KR); Hanjin Lim, Suwon-si (KR); Hyungsuk Jung, Suwon-si (KR)

(21) Appl. No.: 18/601,032

(22) Filed: Mar. 11, 2024

(30) Foreign Application Priority Data
Mar. 24, 2023 (KR) 10-2023-0039312

(51) Int. Cl. H10B 12/00

(52) U.S. Cl. CPC H01L 28/75; H01L 28/65; H10B 12/31; H10B 12/482; H10B 12/488

(57) ABSTRACT

A semiconductor memory device includes an upper electrode, a lower electrode, an anti-ferroelectric layer disposed between the upper electrode and the lower electrode and including an anti-ferroelectric, an oxide layer disposed on a first surface of the anti-ferroelectric layer and including a high dielectric material, and a metal oxide layer disposed on a second surface of the anti-ferroelectric layer opposite to the first surface. A thickness of each of the oxide layer and the metal oxide layer is less than a thickness of the anti-ferroelectric layer.

### CROSS-REFERENCE TO RELATED APPLICATION

This application claims priority under 35 U.S.C. § 119 to Korean Patent Application No. 10-2023-0039312, filed on Mar. 24, 2023 in the Korean Intellectual Property Office, the disclosure of which is incorporated by reference herein in its entirety.

### TECHNICAL FIELD

Embodiments of the inventive concept relate to a semiconductor memory device, and more particularly, to a semiconductor memory device including a capacitor.

### DISCUSSION OF RELATED ART

As semiconductor memory devices are highly integrated, individual circuit patterns have been miniaturized to implement more semiconductor memory devices in the same area. In other words, as the degree of integration of the semiconductor memory device increases, the design rule for components of the semiconductor memory device is decreasing.

### SUMMARY

Embodiments of the inventive concept provide a semiconductor memory device including a capacitor with increased performance and reliability.

According to an embodiment of the inventive concept, a semiconductor memory device includes an upper electrode, a lower electrode, an anti-ferroelectric layer disposed between the upper electrode and the lower electrode and including an anti-ferroelectric, an oxide layer disposed on a first surface of the anti-ferroelectric layer and including a high dielectric material, and a metal oxide layer disposed on a second surface of the anti-ferroelectric layer opposite to the first surface. A thickness of each of the oxide layer and the metal oxide layer is less than a thickness of the anti-ferroelectric layer.

According to an embodiment of the inventive concept, a semiconductor memory device includes an upper electrode, a lower electrode, a dielectric structure disposed between the upper electrode and the lower electrode, an oxide layer disposed between the lower electrode and the dielectric structure and including a high dielectric material, and a metal oxide layer disposed between the upper electrode and the dielectric structure and including a metal material. The dielectric structure includes at least one anti-ferroelectric layer including an anti-ferroelectric, a thickness of each of the oxide layer and the metal oxide layer in a direction orthogonal to an upper surface of the upper electrode is less than a thickness of the dielectric structure, the oxide layer is in contact with the lower electrode, and the metal oxide layer is in contact with the upper electrode.

According to an embodiment of the inventive concept, a semiconductor memory device includes a substrate, an active region defined by a device separation layer formed on the substrate, a word line crossing the active region and extending in a first direction on the substrate, a bit line extending in a second direction orthogonal to the first direction on the substrate, and a capacitor disposed at a higher level than the bit line. The capacitor includes at least one anti-ferroelectric layer including an upper electrode, a lower electrode, and an anti-ferroelectric disposed between the upper electrode and the lower electrode, an oxide layer disposed between the upper electrode and the anti-ferroelectric layer and including a high dielectric material, and a metal oxide layer disposed between the lower electrode and the anti-ferroelectric layer and including a metal material. A thickness of each of the oxide layer and the metal oxide layer is less than a thickness of the at least one anti-ferroelectric layer.

### BRIEF DESCRIPTION OF THE DRAWINGS

The above and other features of the present inventive concept will become more apparent by describing in detail embodiments thereof with reference to the accompanying drawings, in which:

FIG. 1 is a schematic plane layout for explaining some compositions of a memory cell array region of a semiconductor memory device according to an embodiment;

FIG. 2 is a cross-sectional view of some components taken along line A-A′ of FIG. 1, illustrating some components of the semiconductor memory device illustrated in FIG. 1;

FIG. 3A is an enlarged cross-sectional view of an example structure of region P of FIG. 2, and FIGS. 3B to 3J are enlarged cross-sectional views for explaining an example structure of the region P illustrated in FIG. 3A;

FIGS. 4A to 4I are cross-sectional views of the semiconductor memory device for explaining a method of manufacturing the semiconductor memory device illustrated in FIG. 2; and

FIGS. 5A and 5B are graphs for explaining effects of the semiconductor memory device according to an embodiment.

### DETAILED DESCRIPTION OF THE EMBODIMENTS

Embodiments of the inventive concept will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

It will be understood that when a component such as a film, a region, a layer, etc., is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationships between components should be interpreted in a like fashion.

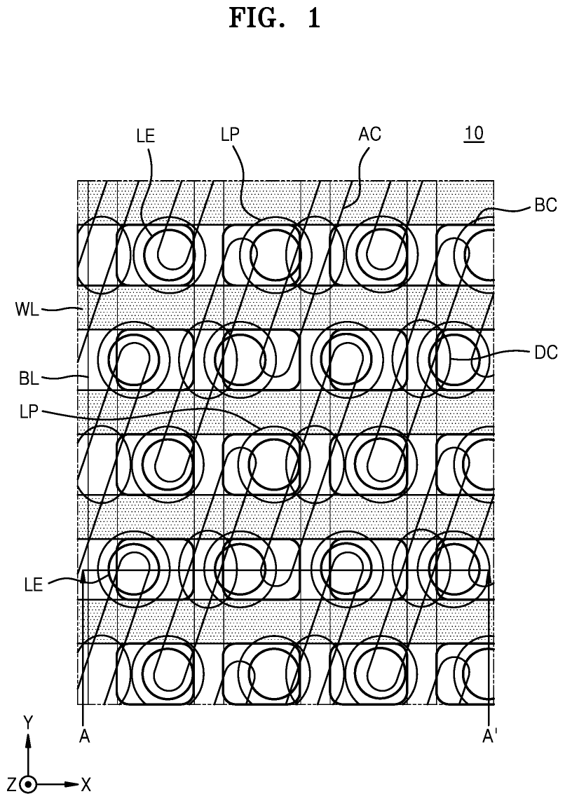

FIG. 1 is a schematic plane layout for explaining some compositions of a memory cell array region of a semiconductor memory device 10 according to embodiments.

Referring to FIG. 1, the semiconductor memory device 10 may include a plurality of active region AC extending horizontally in a diagonal direction with respect to a first direction (X direction) and a second direction (Y direction) on a plane. A plurality of word lines WL may extend parallel to each other along the first direction (X direction) across the plurality of active regions AC. On the plurality of word lines WL, a plurality of bit lines BL may extend parallel to each other along the second direction (Y direction) that crosses the first direction (X direction). The plurality of bit lines BL may each be connected to the active region AC through a direct contact DC. A plurality of buried contacts BC may be disposed between two adjacent bit lines BL among the plurality of bit lines BL. A plurality of conductive landing pads LP may be disposed on the plurality of buried contacts BC. Each of the plurality of conductive landing pads LP may overlap at least a portion of the buried contact BC. A plurality of lower electrodes LE may be spaced apart from each other on the plurality of conductive landing pads LP. The plurality of lower electrodes LE may be connected to the plurality of active region AC through the plurality of buried contacts BC and the plurality of conductive landing pads LP.

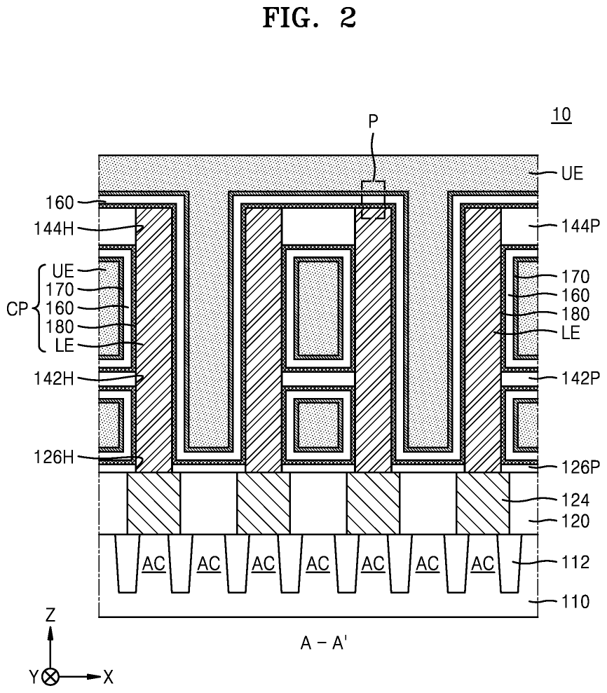

FIG. 2 is a cross-sectional view of some components taken along line A-A′ of FIG. 1, which illustrates some components of the semiconductor memory device illustrated in FIG. 1.

Referring to FIG. 2, the semiconductor memory device 10 may include a substrate 110 including a plurality of active regions AC and a lower structure 120 formed on the substrate 110. A plurality of conductive regions 124 may penetrate the lower structure 120 to be connected to the plurality of active regions AC.

The substrate 110 may include a semiconductor element such as, for example, Si, Ge, or a compound semiconductor such as, for example, SiC, GaAs, InAs, and InP. The substrate 110 may include, for example, a semiconductor substrate, at least one insulating layer formed on the semiconductor substrate, or structures including at least one conductive region. The conductive region may include, for example, a well doped with impurities or a structure doped with impurities. A device separation layer 112 defining the plurality of active regions AC may be formed on the substrate 110. The device separation layer 112 may include, for example, an oxide film, a nitride film, or a combination thereof. In example embodiments, the device separation layer 112 may have a variety of structures, such as the shallow trench isolation (STI) structure.

In some embodiments, the lower structure 120 may include an insulating layer including, for example, a silicon oxide film, a silicon nitride film, or a combination thereof. In some embodiments, the lower structure 120 may include various conductive regions such as, for example, a wiring layer a contact plug, a transistor, etc., and an insulating layer that insulates the conductive regions from each other. The plurality of conductive regions 124 may include, for example, polysilicon, metal, conductive metal nitride, metal silicide, or a combination thereof. The lower structure 120 may include the plurality of bit lines BL described with reference to FIG. 1. The plurality of conductive regions 124 may each include the buried contact BC and the conductive landing pad LP described with reference to FIG. 1.

An insulating pattern 126P including a plurality of openings 126H overlapping the plurality of conductive regions 124 in a third direction (the Z direction) may be disposed on the lower structure 120 and the plurality of conductive regions 124. The insulating pattern 126P may include, for example, a silicon nitride film (SiN), a silicon carbon nitride film (SiCN), a silicon boron nitride film (SiBN), or a combination thereof. The terms “SiN”, “SiCN”, and “SiBN” as used herein are the materials made of elements included in each term, and are not chemical formula that represent stoichiometric relationship.

A capacitor CP may be disposed on the plurality of conductive regions 124. The capacitor CP may include a lower electrode LE, a dielectric structure 160 covering the lower electrode LE, and an upper electrode UE covering the dielectric structure 160 and spaced apart from the lower electrode LE with the dielectric structure 160 disposed therebetween.

The capacitor CP may further include an oxide layer 170 disposed between the dielectric structure 160 and the upper electrode UE and a metal oxide layer 180 disposed between the dielectric structure 160 and the lower electrode LE.

The insulating pattern 126P may be disposed adjacent to the lower end of each of the plurality of lower electrodes LE. Each of the plurality of lower electrodes LE may have a pillar shape extending in a direction away from the substrate 110 along the third direction (the Z direction) through the opening 126H of the insulating pattern 126P from an upper surface of the conductive region LE. In the drawings, the plurality of lower electrodes LE each have a pillar shape, but embodiments of the disclosure are not limited thereto. For example, the plurality of lower electrodes LE may each have a cross-sectional structure of a cup shape or cylinder shape with a closed bottom portion according to embodiments.

For example, the plurality of lower electrodes LE may be supported by a lower supporter 142P and an upper supporter 144P. The plurality of lower electrodes LE and the upper electrode UE may face each other with the dielectric structure 160 disposed therebetween.

As shown in FIG. 2, the upper supporter 144P may surround the upper end of each of the plurality of lower electrodes LE and extend in parallel with the substrate 110. A plurality of holes 144H through which the plurality of lower electrodes LE penetrates may be formed in the upper supporter 144P. The inner sidewalls of each of the plurality of holes 144H formed in the upper supporter 144P may be in contact with the outer sidewall of the lower electrode LE. The upper surface of each of the plurality of lower electrodes LEI and the upper surface of the upper supporter 144P may be on the same plane.

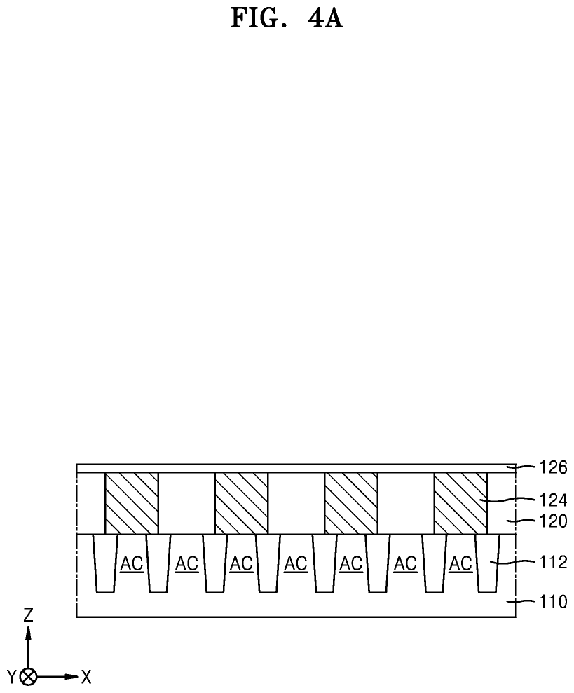

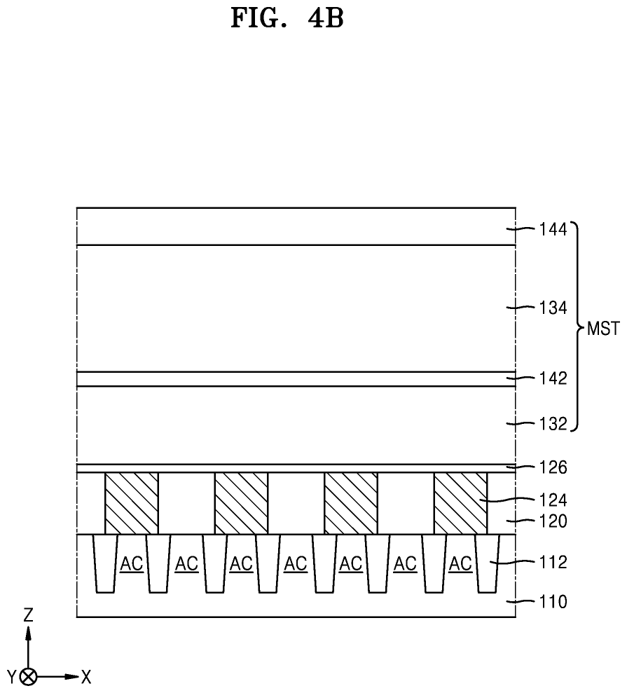

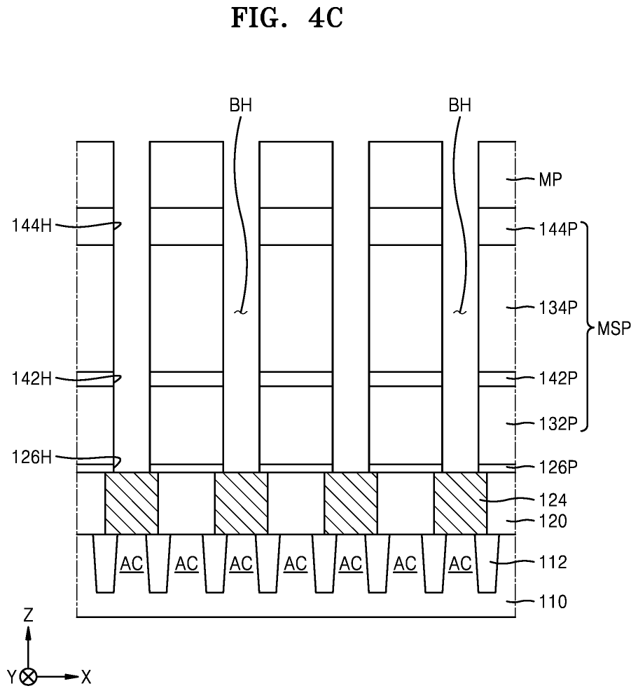

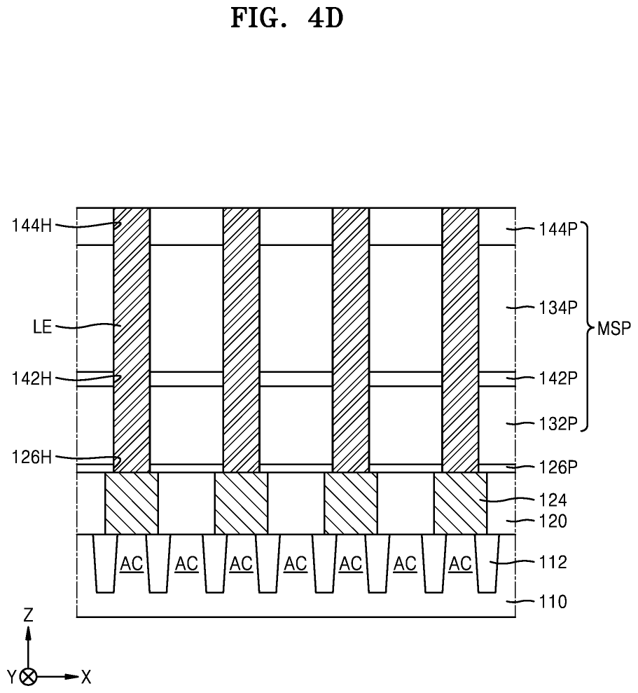

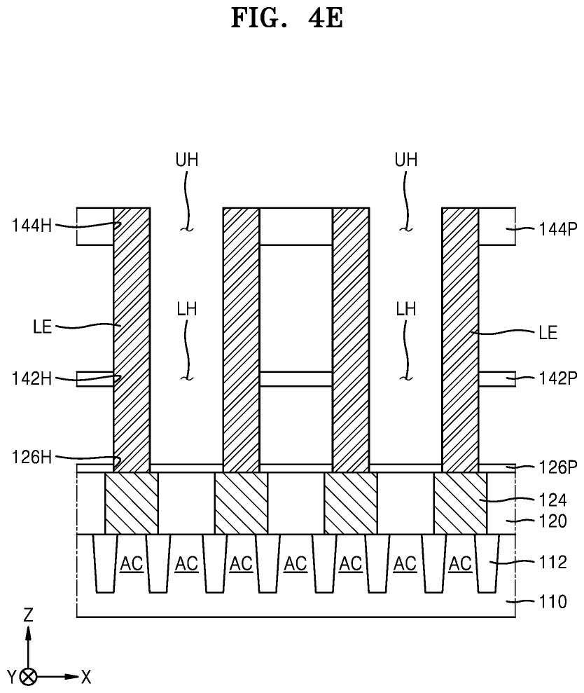

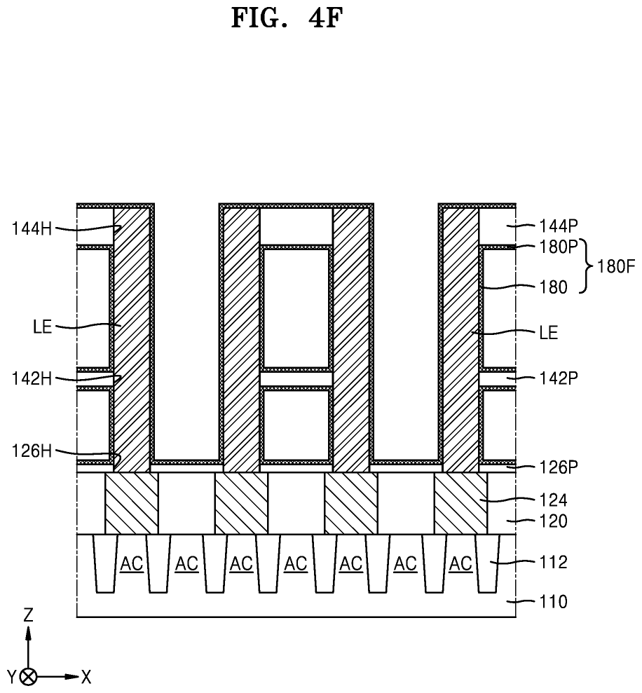

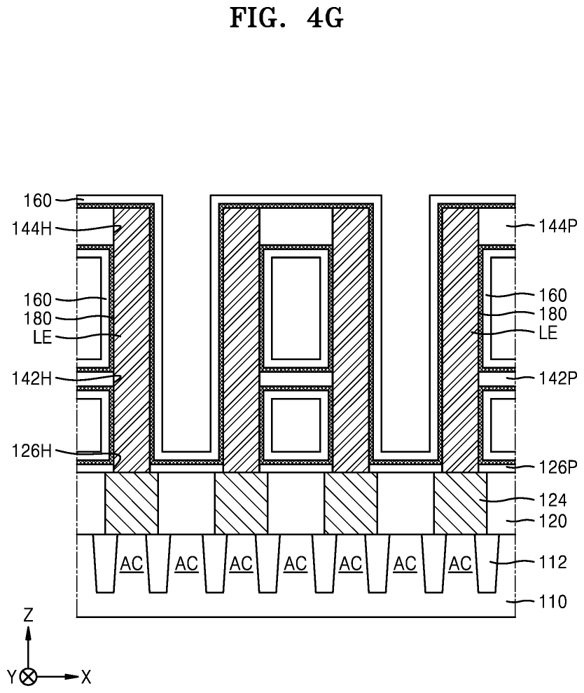

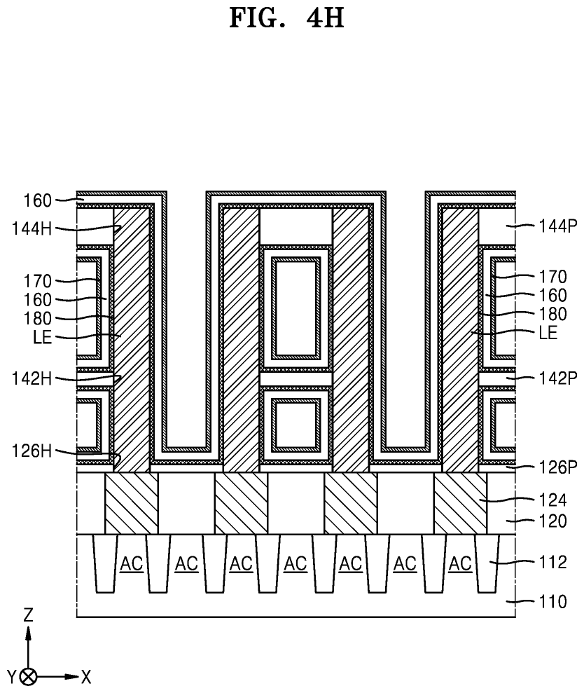

The lower supporter 142P may extend in parallel to the substrate 110 between the substrate 110 and the upper supporter 144P and may be in contact with the outer sidewall of the plurality of lower electrodes LE. The plurality of holes 142H through which the plurality of lower electrodes LE penetrate and a plurality of lower holes LH (refer to FIG. 4E) may be formed in the lower supporter 142P. The plurality of lower electrodes LE may penetrate through the plurality of holes 144H formed in the upper supporter 144P and the plurality of holes 142H formed in the lower supporter 142P to extend in the third direction (the Z direction).

The lower supporter 142P and the upper supporter 144P may each include, for example, a silicon nitride film (SiN), a silicon carbon nitride film (SiCN), a silicon boron nitride film (SiBN), or a combination thereof. In example embodiments, the lower supporter 142P and the upper supporter 144P may include the same material. In example embodiments, the lower supporter 142P and the upper supporter 144P may include different materials from each other. In an embodiment, the lower supporter 142P and the upper supporter 144P may each include SiCN. In some embodiments, the lower supporter 142P may include SiCN, and the upper supporter 144P may include SiBN. However, the inventive concept is not limited thereto.

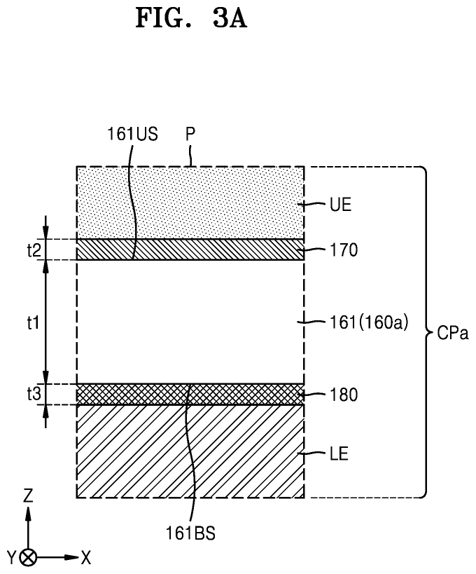

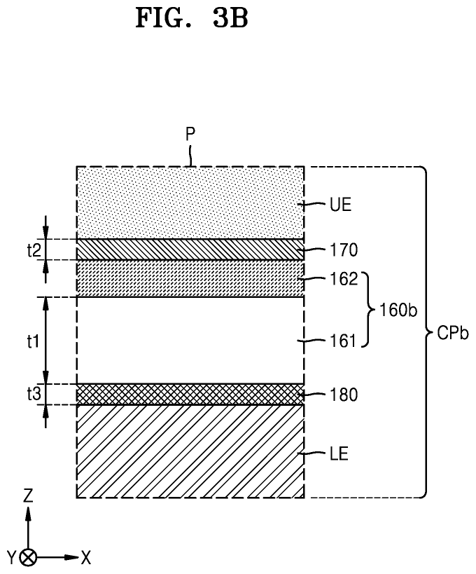

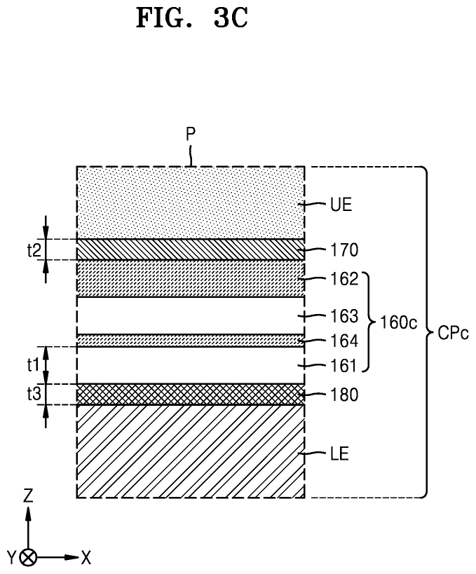

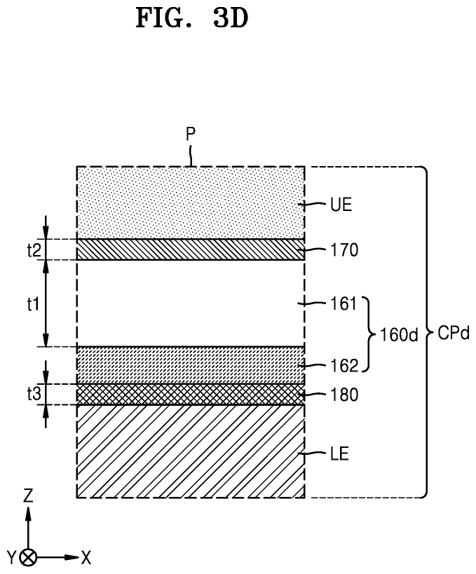

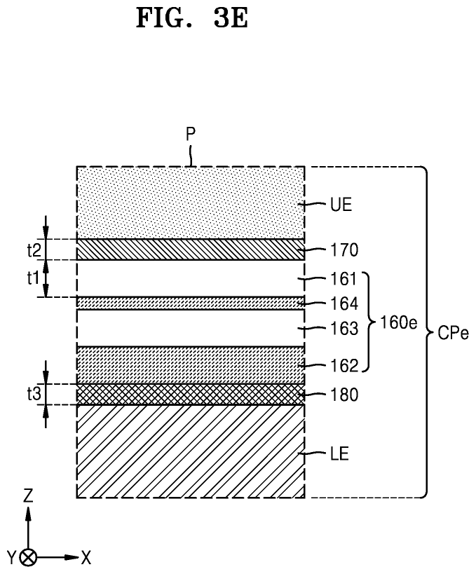

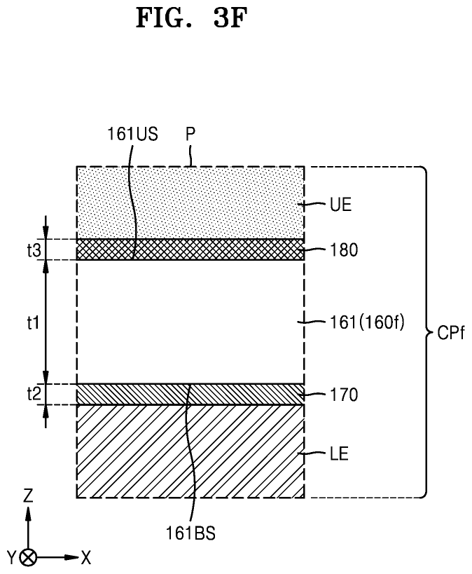

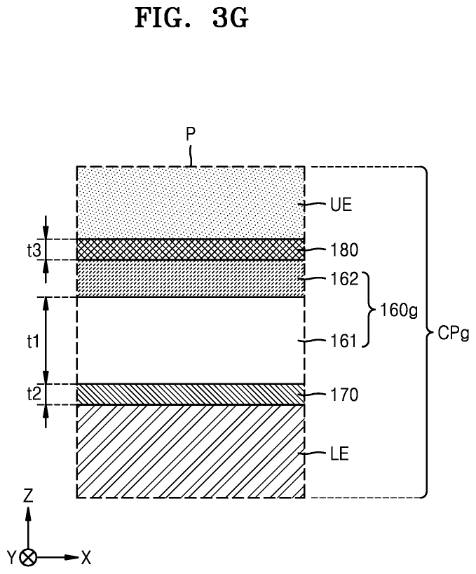

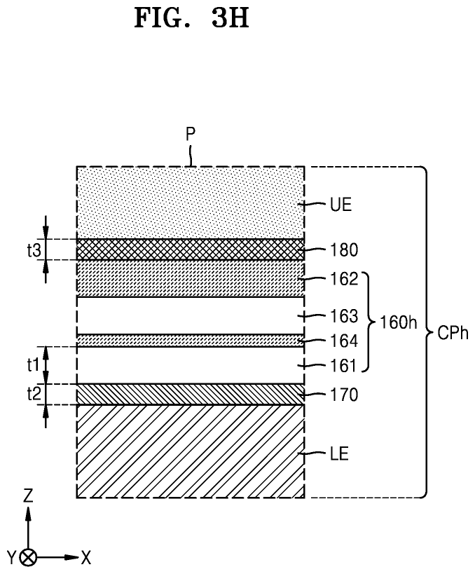

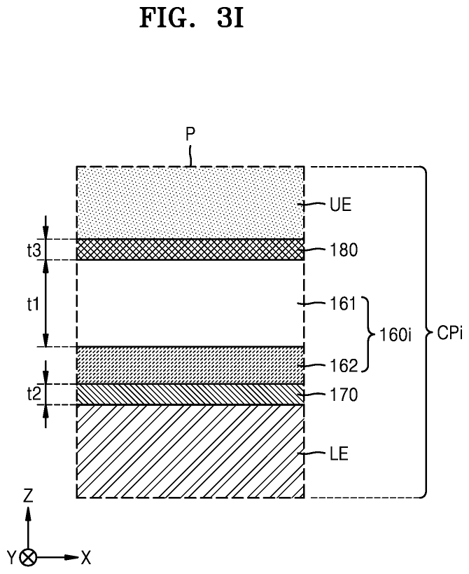

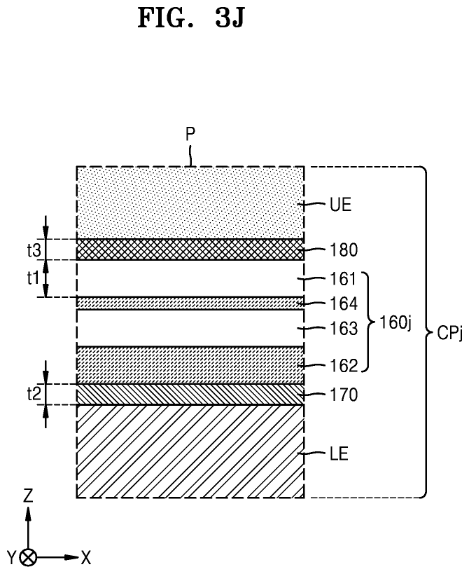

FIG. 3A is an enlarged cross-sectional view of an example structure of region P of FIG. 2, and FIGS. 3B to 3J are enlarged cross-sectional views for explaining an example structure of the region P illustrated in FIG. 3A.

Referring to FIG. 3A, a capacitor CPa may include the upper electrode UE, the lower electrode LE spaced apart from the upper electrode UE, a dielectric structure 160a disposed between the upper electrode UE and the lower electrode LE, the oxide layer 170 disposed between the upper electrode UE and the dielectric structure 160a, and the metal oxide layer 180 disposed between the lower electrode LE and the dielectric structure 160a. The dielectric structure 160a provides a first surface 161US in parallel to the first direction (the X direction) and the second direction (the Y direction), both directions orthogonal to the third direction (the Z direction), and a second surface 161BS opposite to the first surface 161US. The oxide layer 170 may be disposed on the first surface 161US, and the metal oxide layer 180 may be disposed on the second surface 161BS.

The lower electrode LE may include a metal-containing layer including a first metal. The upper electrode UE may face the lower electrode LE with the dielectric structure 160a disposed therebetween. In example embodiments, the lower electrode LE may include the same metal as the first metal. In example embodiments, the lower electrode LE may include a different material from the first metal.

The lower electrode LE and the upper electrode UE may each include, for example, a metal film, a conductive metal oxide film, a conductive metal nitride film, a conductive metal oxide film, or a combination thereof. In example embodiments, the lower electrode LE and the upper electrode UE may each include, for example, Ti, Ti oxide, Ti nitride, Ti oxynitride, Nb, Nb oxide, Nb nitride, Nb oxynitride, Co, Co oxide, Co nitride, Co oxynitride, Sn, Sn oxide, Sn nitride, Sn oxynitride, or a combination thereof. For example, the lower electrode LE and the upper electrode UE may each include NbN, TiN, CON, SnO₂, or a combination thereof. In example embodiments, the lower electrode LE and the upper electrode UE may each include TaN, TiAlN, TaAlN, W, Ru, RuO₂, SrRuO₃, Ir, IrO₂, Pt, PtO, SRO(SrRuO₃), BSRO((Ba,Sr)RuO₃), CRO(CaRuO₃), LSCO((La,Sr)CoO₃), or a combination thereof. However, the components of the lower electrode LE and the upper electrode UE each are not limited to the above examples.

The thickness of the lower electrode LE and the upper electrode UE may each be greater than about 100 Å. In embodiments, the thickness of the lower electrode LE may be greater than the thickness of the upper electrode UE. However, embodiments are not limited to the above, and the thickness of the lower electrode LE may be substantially the same or less than the thickness of the upper electrode UE according to embodiments.

The dielectric structure 160a according to an embodiment may include an anti-ferroelectric layer 161 including an anti-ferroelectric. The anti-ferroelectric layer 161 may include at least one of, for example, HfO, ZrO, SiO, AlO, CeO, YO, or LaO, and may further include dopants such as, for example, Si, Al, Zr, Y, La, Gd, Sr, Hf, and Ce. The example materials indicate ferroelectricity or anti-ferroelectricity depending on the stress state between the crystalline phase and/or an adjacent layer. In an embodiment, the anti-ferroelectric may include at least one of ZrO₂, PbZrO₃, AgNbO₃, or HfₓZr₁₋ₓO₂, and, in this case, x may a positive number smaller than 0.5.

Although the anti-ferroelectric material includes a ferroelectric domain in which electric dipoles are arrayed, the remnant polarization may show a value of 0 or close to 0 with the absence of an external electric field being applied. In other words, when an electric field is not applied to the anti-ferroelectric material, ideally, the electric dipoles with opposite polarization may have the same ratios, and thus, the remnant polarization may be 0 or close to 0. The polar direction of the anti-ferroelectric materials may be switched when the external electric field is applied. The anti-ferroelectric layer 161 may have substantially non-hysteresis behavioral characteristics in the change of polarization according to the external electric field. In other words, in embodiments, the anti-ferroelectric layer 161 does not have or substantially does not have hysteresis characteristics during a domain switching operation.

In example embodiments, the oxide layer 170 may be disposed between the upper electrode UE and the dielectric structure 160a. The oxide layer 170 may be in contact with the first surface 161US of the dielectric structure 160a. In an embodiment, the oxide layer 170 may include a high dielectric material. The term “high dielectric material” used herein refers to a dielectric layer having a higher dielectric constant than those of the silicon oxide film and the silicon nitride film. In example embodiments, a high dielectric material may include, for example, at least one of HfO₂, ZrO₂, Al₂O₃, La₂O₃, Ta₂O₃, Nb₂O₅, CeO₂, TiO₂, GeO₂, Y₂O₃, Ta₂O₅, SrO, or Ga₂O₃. In an embodiment, the high dielectric material may have a dielectric constant of about 10 or more and about 100 or less. In addition, according to an embodiment, the high dielectric material may have a band gap energy of about 4.0 eV or more and about 6.0 eV or less.

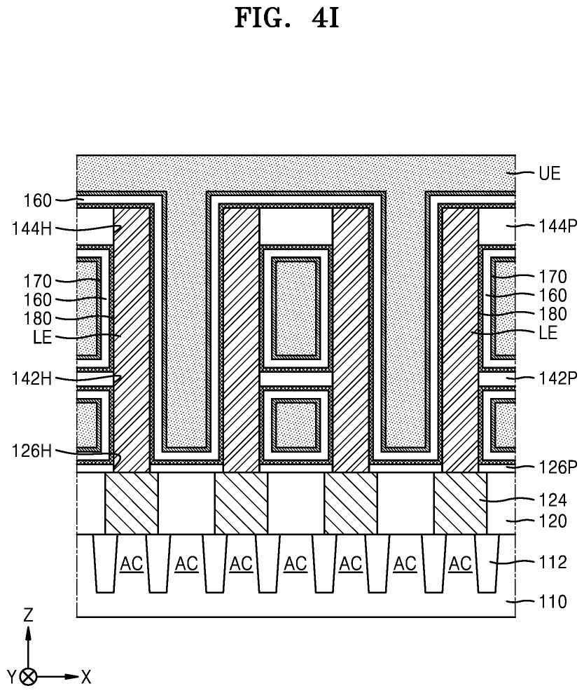

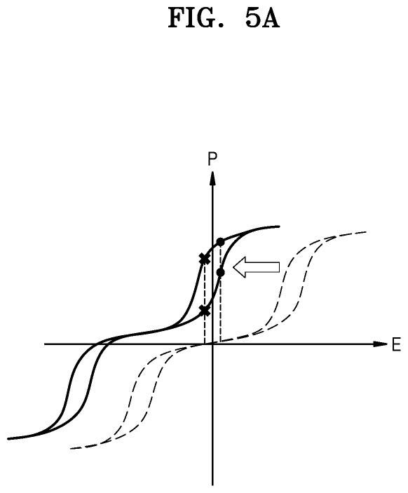

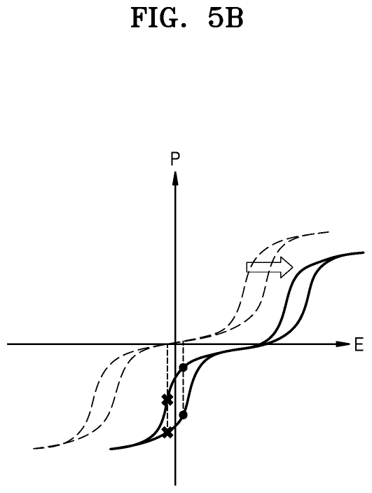

In example embodiments, the metal oxide layer 180 may be disposed between the lower electrode LE and the dielectric structure 160a. The metal oxide layer 180 may be in contact with the second surface 161BS of the dielectric structure 160a. In an embodiment, the metal oxide layer 180 may include, for example, at least one of Ta⁺⁵, W⁺⁶, Nb⁺⁵, Mo⁺⁶, In⁺³, Zn⁺², Ga⁺³, or Ni⁺². In a general capacitor, the applied voltage applied to the electrode for polarization to be formed in the dielectric is to be high due to oxide, etc. naturally formed between the dielectric and the electrode. Thus, high voltage is applied to the capacitor to generate polarization in the dielectric. In this case, when the metal oxide layer 180 having a higher conductivity than the oxide, etc. is disposed between the lower electrode LE and the dielectric structure 160a, polarization may be generated in the dielectric structure 160a even when a lower positive voltage is applied to the upper and lower electrodes UE and LE. On the other hand, when the oxide layer 170 including a high dielectric material is disposed between the upper electrode UE and the dielectric structure 160a, polarization may be generated in the dielectric structure 160a when a higher negative voltage is applied to the upper and lower electrodes UE and LE. That is, as will be described below with reference to FIG. 5A, an effect in which a graph illustrating a relationship between an electric field and polarization of the anti-ferroelectric layer 161 is shifted as a whole may occur.

In an embodiment, a vertical distance between the oxide layer 170 and the metal oxide layer 180 may be about 5 Å or more and less than about 100 Å. That is, a thickness t1 of the dielectric structure 160a may be about 5 Å or more and less than about 100 Å. A thickness t2 of the oxide layer 170 and a thickness t3 of the metal oxide layer 180 may each be thinner than the thickness of the anti-ferroelectric layer 161. In other words, the thickness t2 of the oxide layer 170 and the thickness t3 of the metal oxide layer 180 may each be thinner than the thickness t1 of the dielectric structure 160a. In this case, the thickness t2 of the oxide layer 170 and the thickness t3 of the metal oxide layer 180 may be at least about 5 Å.

In an embodiment, the upper electrode UE may be in contact with the oxide layer 170, and the lower electrode LE may be in contact with the metal oxide layer 180. That is, an interface may be formed between the upper electrode UE and the oxide layer 170, and an interface may be formed between the lower electrode LE and the metal oxide layer 180. The dielectric structure 160a may be in contact with each of the oxide layer 170 and the metal oxide layer 180. That is, the anti-ferroelectric layer 161 constituting the dielectric structure 160a may form an interface with each of the oxide layer 170 and the metal oxide layer 180.

FIG. 3B is an enlarged cross-sectional view for explaining an example structure of the region P illustrated in FIG. 3A. FIGS. 3A and 3B are similar to each other except that a dielectric structure 160b of FIG. 3B further includes a ferroelectric layer 162. For convenience of explanation, a further description of components and technical aspects previously described with reference to FIG. 3A will be omitted or simplified.

Referring to FIG. 3B, a capacitor CPb of the semiconductor memory device according to an embodiment may include the dielectric structure 160b disposed between the oxide layer 170 and the metal oxide layer 180. The dielectric structure 160b may include a first ferroelectric layer 162 disposed between the first anti-ferroelectric layer 161 and the oxide layer 170. The first ferroelectric layer 162 may include a ferroelectric. Because the charge distribution of the ferroelectric in a unit cell is non-centrosymmetric in a crystallized material structure, the ferroelectric may have a voluntary electric dipole, or a spontaneous polarization. The ferroelectric may have a remnant polarization due to the electric dipole even in the absence of an external electric field, and the polarization may be switched on a domain level by the external electric field.

In an embodiment, the ferroelectric may include oxides of, for example, Si, Al, Hf, or Zr. The ferroelectric may include, for example, HfO₂, ZrO₂, HfₓZr₁₋ₓO₂, and a combination thereof. In this case, x may be a positive number smaller than 1. The ferroelectric may include one or more of the above-described oxides as a base material, and may further include, for example, C, Si, Ge, Sn, Pb, Al, Y, La, Gd, Mg, Ca, Sr Ba, Ti, Zr, Hf, or N as a dopant material. The content of the dopant material may be more than about 0 at %, about 0.2 at % or more, about 0.5 at % or more, about 1 at % or more, about 2 at % or more, about 3 at % or more, about 10 at % or less, about 8 at % or less, about 7 at % or less, or about 6 at % or less with respect to a base metal element. However, the above are examples and embodiments are not limited thereto.

In an embodiment, the thickness of the first anti-ferroelectric layer 161 may be greater than the thickness of the first ferroelectric layer 162. For example, the thickness of the first anti-ferroelectric layer 161 may be at least about 1.5 times greater than the thickness of the first ferroelectric layer 162. If the thickness of the first anti-ferroelectric layer 161 is about 1.5 times less than the thickness of the first ferroelectric layer 162, the dielectric structure 160b may lose the characteristics of the anti-ferroelectric. Accordingly, in embodiments, the thickness of the first anti-ferroelectric layer 161 is at least about 1.5 times greater than the thickness of the first ferroelectric layer 162.

FIG. 3C is an enlarged cross-sectional view for explaining an example structure of the region P illustrated in FIG. 3A. FIGS. 3C and FIG. 3A are similar to each other except that a dielectric structure 160c of FIG. 3C includes a plurality of anti-ferroelectric layers 161 and 163 (hereinafter, also referred to as a first anti-ferroelectric layer 161 and a second anti-ferroelectric layer 163) and a plurality of ferroelectric layers 162 and 164 (hereinafter, also referred to as a first ferroelectric layer 162 and a second ferroelectric layer 164). For convenience of explanation, a further description of components and technical aspects previously described with reference to FIG. 3A will be omitted or simplified.

Referring to FIG. 3C, a capacitor CPc of the semiconductor memory device according to an embodiment may include the dielectric structure 160c disposed between the oxide layer 170 and the metal oxide layer 180. The dielectric structure 160c may include the first anti-ferroelectric layer 161 and the second anti-ferroelectric layer 163, both including the anti-ferroelectric. In addition, the dielectric structure 160c may include the first ferroelectric layer 162 and the second ferroelectric layer 164, both including the ferroelectric. Although two of each anti-ferroelectrics and ferroelectrics are illustrated in the drawings, embodiments are not limited thereto, and there may be three or more of each anti-ferroelectrics and ferroelectrics according to embodiments. The first anti-ferroelectric layer 161, the second anti-ferroelectric layer 163, the first ferroelectric layer 162, and the second ferroelectric layer 164 may each have a thickness of at least about 5 Å. In addition, each of the plurality of anti-ferroelectric layers 161 and 163 and the plurality of ferroelectric layers 162 and 164 may be laminated alternately between the oxide layer 170 and the metal oxide layer 180. Similarly, according to an embodiment, three or more of anti-ferroelectric layers and three or more of ferroelectric layers may be laminated alternately.

As shown in FIG. 3C, among the plurality of ferroelectric layers 162 and 164, the first ferroelectric layer 162, which is disposed closest to the oxide layer 170, may be disposed closer to the oxide layer 170 than the second anti-ferroelectric layer 163, which is disposed closest to the oxide layer 170 among the plurality of anti-ferroelectric layers 161 and 163.

In an embodiment, the sum of the thicknesses of the first and second anti-ferroelectric layers 161 and 163 may be greater than the sum of the thicknesses of the first and second ferroelectric layers 162 and 164. For example, the sum of the thicknesses of the first and second anti-ferroelectric layers 161 and 163 may be at least about 1.5 times greater than the sum of the thicknesses of the first and second ferroelectric layers 162 and 164. If the sum of the thicknesses of the first and second anti-ferroelectric layers 161 and 163 is about 1.5 times less than the sum of the thicknesses of the first and second ferroelectric layers 162 and 164, the dielectric structure 160c may lose the characteristics of the anti-ferroelectric layer. Accordingly, the sum of the thicknesses of the first and second anti-ferroelectric layers 161 and 163 is at least about 1.5 times greater than the sum of the thicknesses of the first and second ferroelectric layers 162 and 164 according to embodiments.

FIG. 3D is an enlarged cross-sectional view for explaining an example structure of the region P illustrated in FIG. 3A. FIGS. 3D and 3C are similar to each other except that the arrangement of the first anti-ferroelectric layer 161 and the first ferroelectric layer 162 in FIG. 3C is different from that of FIG. 3D. For convenience of explanation, a further description of components and technical aspects previously described with reference to FIG. 3A will be omitted or simplified.

Referring to FIG. 3D, a capacitor CPd of the semiconductor memory device according to an embodiment may include a dielectric structure 160d disposed between the oxide layer 170 and the metal oxide layer 180. The dielectric structure 160d may include a first anti-ferroelectric layer 161 disposed between the oxide layer 170 and the metal oxide layer 180 and the first ferroelectric layer 162 disposed between the first anti-ferroelectric layer 161 and the metal oxide layer 180. That is, the first anti-ferroelectric layer 161 may be disposed between the oxide layer 170 and the first ferroelectric layer 162.

In an embodiment, the thickness of the first anti-ferroelectric layer 161 may be greater than the thickness of the first ferroelectric layer 162. For example, the thickness of the first anti-ferroelectric layer 161 may be at least about 1.5 times greater than the thickness of the first ferroelectric layer 162. If the thickness of the first anti-ferroelectric layer 161 is about 1.5 times less than the thickness of the first ferroelectric layer 162, the dielectric structure 160d may lose the characteristics of the first anti-ferroelectric. Accordingly, the thickness of the first anti-ferroelectric layer 161 is at least about 1.5 times greater than the thickness of the first ferroelectric layer 162 according to embodiments.

FIG. 3E is an enlarged cross-sectional view for explaining an example structure of the region P illustrated in FIG. 3A. FIG. 3E is similar to FIG. 3C, except that the arrangement of the first and second anti-ferroelectric layers 161 and 163 and the first and second ferroelectric layers 162 and 164 of FIG. 3E is different from that of FIG. 3C. For convenience of explanation, a further description of components and technical aspects previously described with reference to FIG. 3C will be omitted or simplified.

Referring to FIG. 3E, a capacitor CPe of the semiconductor memory device according to an embodiment may include a dielectric structure 160e disposed between the oxide layer 170 and the metal oxide layer 180. The dielectric structure 160e may include the first anti-ferroelectric layer 161 and the second anti-ferroelectric layer 163, both including the anti-ferroelectric. In addition, the dielectric structure 160e may include the first ferroelectric layer 162 and the second ferroelectric layer 164, both including the ferroelectric. Although two of each anti-ferroelectrics and ferroelectrics are illustrated in the drawings, embodiments are not limited thereto, and there may be three or more of each anti-ferroelectrics and ferroelectrics according to embodiments. The first anti-ferroelectric layer 161, the second anti-ferroelectric layer 163, the first ferroelectric layer 162, and the second ferroelectric layer 164 may each have a thickness of at least about 5 Å. In addition, each of the plurality of anti-ferroelectric layers 161 and 163 and the plurality of ferroelectric layers 162 and 164 may be laminated alternately between the oxide layer 170 and the metal oxide layer 180. Similarly, according to an embodiment, three or more of anti-ferroelectric layers and three or more of ferroelectric layers may be laminated alternately.

As shown in FIG. 3E, among the plurality of anti-ferroelectric layers 161 and 163, the first anti-ferroelectric layer 161, which is disposed the closest to the oxide layer 170, may be disposed closer to the oxide layer 170 than the second ferroelectric layer 164, which is disposed closest to the oxide layer 170 among the plurality of ferroelectric layers 162 and 164.

FIG. 3F is an enlarged cross-sectional view for explaining an example structure of the region P illustrated in FIG. 3A. FIGS. 3F and 3A are similar to each other except that the arrangement of the oxide layer 170 and the metal oxide layer 180 in FIG. 3F is different from that of FIG. 3A. For convenience of explanation, a further description of components and technical aspects previously described with reference to FIG. 3A will be omitted or simplified.

Referring to FIG. 3F, a capacitor CPf of the semiconductor memory device according to an embodiment may include a dielectric structure 160f disposed between the oxide layer 170 and the metal oxide layer 180. The dielectric structure 160f may include the first anti-ferroelectric layer 161 disposed between the oxide layer 170 and the metal oxide layer 180.

In example embodiments, the oxide layer 170 may be disposed between the lower electrode LE and the dielectric structure 160f. The oxide layer 170 may be in contact with the second surface 161BS of the dielectric structure 160f. In addition, the metal oxide layer 180 may be disposed between the upper electrode UE and the dielectric structure 160f. The metal oxide layer 180 may be in contact with the first surface 161US of the dielectric structure 160f.

FIG. 3G is an enlarged cross-sectional view for explaining an example structure of the region P illustrated in FIG. 3A. FIGS. 3G and 3B are similar to each other except that the arrangement of the oxide layer 170 and the metal oxide layer 180 in FIG. 3G is different from that of FIG. 3B. For convenience of explanation, a further description of components and technical aspects previously described with reference to FIG. 3B will be omitted or simplified.

Referring to FIG. 3G, a capacitor CPg of the semiconductor memory device according to an embodiment may include a dielectric structure 160g disposed between the oxide layer 170 and the metal oxide layer 180. In this case, the oxide layer 170 may form an interface with the lower electrode LE, and the metal oxide layer 180 may form an interface with the upper electrode UE. A surface of the first anti-ferroelectric layer 161 of the dielectric structure 160g may be in contact with the oxide layer 170, and the other surface opposite to the surface of the first anti-ferroelectric layer 161 may be in contact with the first ferroelectric layer 162. A surface opposite to the surface of the first ferroelectric layer 162 in contact with the first anti-ferroelectric layer 161 may be in contact with the metal oxide layer 180.

FIG. 3H is an enlarged cross-sectional view for explaining an example structure of the region P illustrated in FIG. 3A. FIGS. 3H and 3C are similar to each other except that the arrangement of the oxide layer 170 and the metal oxide layer 180 in FIG. 3H is different from that of FIG. 3C. For convenience of explanation, a further description of components and technical aspects previously described with reference to FIG. 3C will be omitted or simplified.

Referring to FIG. 3H, a capacitor CPh of the semiconductor memory device according to an embodiment may include a dielectric structure 160h disposed between the oxide layer 170 and the metal oxide layer 180. In this case, the oxide layer 170 may form an interface with the lower electrode LE, and the metal oxide layer 180 may form an interface with the upper electrode UE. The plurality of anti-ferroelectric layers 161 and 163 and the plurality of ferroelectric layers 162 and 164 of the dielectric structure 160h may be alternately laminated between the oxide layer 170 and the metal oxide layer 180. In this case, among the plurality of anti-ferroelectric layers 161 and 163, the first anti-ferroelectric layer 161, which is disposed closest to the oxide layer 170, may be disposed closer to the oxide layer 170 than the second ferroelectric layer 164, which is disposed closest to the oxide layer 170 among the plurality of ferroelectric layers 162 and 164.

FIG. 3I is an enlarged cross-sectional view for explaining an example structure of the region P illustrated in FIG. 3A. FIGS. 3I and 3D are similar to each other except that the arrangement of the oxide layer 170 and the metal oxide layer 180 in FIG. 3I is different from that of FIG. 3D. For convenience of explanation, a further description of components and technical aspects previously described with reference to FIG. 3D will be omitted or simplified.

Referring to FIG. 3I, a capacitor CPi of the semiconductor memory device according to an embodiment may include a dielectric structure 160i disposed between the oxide layer 170 and the metal oxide layer 180. In this case, the oxide layer 170 may form an interface with the lower electrode LE, and the metal oxide layer 180 may form an interface with the upper electrode UE. A surface of the first anti-ferroelectric layer 161 of the dielectric structure 160i may be in contact with the metal oxide layer 180, and the other surface opposite to the surface of the first anti-ferroelectric layer 161 may be in contact with the first ferroelectric layer 162. A surface opposite to the surface of the first ferroelectric layer 162 in contact with the first anti-ferroelectric layer 161 may be in contact with the oxide layer 170.

FIG. 3J is an enlarged cross-sectional view for explaining an example structure of the region P illustrated in FIG. 3A. FIGS. 3J and 3E are similar to each other except that the arrangement of the oxide layer 170 and the metal oxide layer 180 in FIG. 3J is different from that of FIG. 3E. For convenience of explanation, a further description of components and technical aspects previously described with reference to FIG. 3E will be omitted or simplified.

Referring to FIG. 3J, a capacitor CPj of the semiconductor memory device according to an embodiment may include the dielectric structure 160j disposed between the oxide layer 170 and the metal oxide layer 180. In this case, the oxide layer 170 may form an interface with the lower electrode LE, and the metal oxide layer 180 may form an interface with the upper electrode UE. The plurality of anti-ferroelectric layers 161 and 163 and the plurality of ferroelectric layers 162 and 164 of the dielectric structure 160j may be alternately laminated between the oxide layer 170 and the metal oxide layer 180. In this case, among the plurality of ferroelectric layers 162 and 164, the first ferroelectric layer 162, which is disposed closest to the oxide layer 170, may be disposed closer to the oxide layer 170 than the second anti-ferroelectric layer 163, which is disposed closest to the oxide layer 170 among the plurality of anti-ferroelectric layers 161 and 163.

In an embodiment according to the inventive concept illustrated in FIGS. 3A to 3J, although the number of each of the plurality of anti-ferroelectric layers 161 and 163 and the plurality of ferroelectric layers 162 and 164 is illustrated to be two at most, embodiments are not limited thereto. For example, according to embodiments, three or more anti-ferroelectric layers and/or three or more ferroelectric layers may be laminated between the oxide layer 170 and the metal oxide layer 180 according to an embodiment.

FIGS. 4A to 4I are cross-sectional views of the semiconductor memory device 10 for explaining a method of manufacturing the semiconductor memory device 10 illustrated in FIG. 2.

Referring to FIG. 4A, the lower structure 120 disposed on the substrate 110 in which the active regions AC are defined by the device separation layer 112, and the conductive regions 124 penetrating through the lower structure 120 and connected to the active regions AC, may be formed. Then, an insulating layer 126 covering the lower structure 120 and the conductive region 124 may be formed.

The insulating layer 126 may be used as an etching stop layer in a subsequent process. The insulating layer 126 may include an insulating material having an etching selectivity with respect to the lower structure 120. In some embodiments, the insulating layer 126 may include, for example, a silicon nitride film (SiN), a silicon carbon nitride film (SiCN), a silicon boron nitride film (SiBN), or a combination thereof.

Referring to FIG. 4B, a mold structure MST may be formed above the insulating layer 126. The mold structure MST may include a plurality of mold layers and a plurality of support layers. For example, the mold structure MST may include a first mold layer 132, a lower support layer 142, a second mold layer 134, and an upper support layer 144. The first mold layer 132 and the second mold layer 134 may each have a relatively high etch rate with respect to an etchant including, for example, ammonium fluoride (NH₄F), hydrofluoric acid (HF), and water, and thus, may include materials removable by a lift-off process by the etchant. In some embodiments, the first mold layer 132 and the second mold layer 134 may each include, for example, an oxide film, a nitride film, or a combination thereof. For example, the first mold layer 132 may include boro phospho silicate glass (BPSG) film. The BPSG film may include at least one of a first portion in which a concentration of a dopant boron (B) changes along the thickness direction of the BPSG film and a second portion in which a concentration of a dopant phosphorus (P) changes along the thickness direction of the BPSG film. The second mold layer 134 may include a multiple insulating layer in which relatively thin silicon oxide films and silicon nitride films are each alternately laminated multiple times, or a silicon nitride film. However, the components of each of the first mold layer 132 and the second mold layer 134 are not limited to the above examples, and various modifications and changes may be made according to embodiments. In addition, the lamination order of the mold structure MST is not limited to the example in FIG. 4B, and various modifications and changes may be made according to embodiments.

The lower support layer 142 and the upper support layer 144 may each include, for example, a silicon nitride film (SiN), a silicon carbon nitride film (SiCN), a silicon boron nitride film (SiBN), or a combination thereof. In example embodiments, the lower support layer 142 and the upper support layer 144 may include the same material. In some example embodiments, the lower support layer 142 and the upper support layer 144 may include different materials from each other. In an embodiment, the lower support layer 142 and the upper support layer 144 may each include a silicon carbon nitride film (SiCN). In an example, the lower support layer 142 may include a silicon carbon nitride film (SiCN), and the upper support layer 144 may include a boron-containing silicon nitride film (SiN). However, the components of each of the lower support layer 142 and the upper support layer 144 are not limited to the above examples, and various modifications and changes may be made according to embodiments.

Referring to FIG. 4C, after forming a mask pattern MP on the mold structure MST in the resulting structure of FIG. 4B, by using the mask pattern MP as an etching mask and the insulating layer 126 as an etching stop layer, anisotropic etching of the mold structure MST may be performed to form a mold structure pattern MSP including a plurality of holes BH. The mold structure pattern MSP may include a first mold pattern 132P, the lower supporter 142P, a second mold pattern 134P, and the upper supporter 144P.

The mask pattern MP may include, for example, a nitride film, an oxide film, a polysilicon film, a photoresist film, or a combination thereof.

The process of forming a plurality of holes BH may further include wet processing of the resulting structure of the anisotropic etching of the mold structure MST. During the anisotropic etching of the mold structure MST and the wet processing of the resulting structure, a portion of the insulating layer 126 may also be etched to obtain an insulating pattern 126P exposing the plurality of conductive regions 124 and including the plurality of openings 126H. In an example process for the wet processing of the structure resulting from the anisotropic etching of the mold structure MST, an etchant including a diluted sulfuric acid peroxide (DSP) solution may be used, but embodiments are not limited thereto.

In the mold structure pattern MSP, a plurality of holes 142H, which are part of the plurality of holes BH, may be formed in the lower supporter 142P, and the plurality of holes 144H, which are part of the plurality of holes BH, may be formed in the upper supporter 144P.

Referring to FIG. 4D, the mask pattern MP may be removed from the resulting structure of FIG. 4C, and the lower electrode LE filling the plurality of holes BH may be formed.

In example embodiments, a conductive layer filling the plurality of holes BH and covering the upper surface of the upper supporter 144P may be formed on the resulting structure of FIG. 4D to form the lower electrode LE. For example, a chemical vapor deposition (CVD), plasma enhanced CVD (PECVD), metal organic CVD (MOCVD), or atomic layer deposition (ALD) process may be used to form the conductive layer. Then, a portion of the conductive layer may be removed by an etchback process or a chemical mechanical polishing (CMP) process such that the upper surface of the upper supporter 144P is exposed.

Referring to FIG. 4E, after removing a portion of the upper supporter 144P from the resulting structure of FIG. 4D to form a plurality of upper holes UH, the second mold pattern 134P may be removed by, for example, a wet process through the plurality of upper holes UH. Subsequently, after removing a portion of the lower supporter 142P exposed through the plurality of upper holes UH, the first mold pattern 132P may be removed by, for example, wet processing through the plurality of lower holes LH to expose the upper surface of the insulating pattern 126P. After the first mold pattern 132P and the second mold pattern 134P are removed, the sidewalls of the plurality of lower electrodes LE may be exposed.

In example embodiments, although etchants including NH₄F, HF, and water may be used to remove the second mold pattern 134P and the first mold pattern 132P through wet processing, embodiments are not limited thereto.

Referring to FIG. 4F, a metal oxide layer 180 covering sidewalls of the exposed plurality of lower electrodes LE, some surfaces of the lower supporter 142P and the upper supporter 144P, and some surfaces of the insulating pattern 126P, may be formed. The metal oxide layer 180 may be formed by applying a metal oxide using, for example, a CVD, MOCVD, PVD, or ALD process. The metal oxide layer 180 may include, for example, Ta⁺⁵, W⁺⁶, Nb⁺⁵, Mo⁺⁶, In⁺³, Zn⁺², Ga⁺³, Ni⁺², or a combination thereof. The metal oxide layer 180 may be formed on exposed sidewalls of the plurality of lower electrodes LE.

Referring to FIG. 4G, a process of forming the dielectric structure 160 covering the metal oxide layer 180 may be performed. In addition to the metal oxide layer 180, exposed surfaces of each of the lower supporter 142P and the upper supporter 144P, and the dielectric structure 160 covering the exposed surfaces of the insulating pattern 126P, may be formed. For example, a CVD, PECVD, MOCVD, or ALD process may be used to form the dielectric structure 160. An annealing process may be performed after a deposition process of covering the metal oxide layer 180 with the dielectric structure 160 is performed. In example embodiments, the annealing process may be performed at a temperature of about 200° C. to about 700° C. The crystallinity of the dielectric structure 160 may be improved by the annealing process, which may be performed in a state in which the dielectric structure 160 is formed.

Referring to FIG. 4H, the oxide layer 170 covering the dielectric structure 160 and including the high dielectric material may be formed. The oxide layer 170 may be formed by applying a metal oxide using, for example, a CVD, MOCVD, PVD, or ALD process. The high dielectric material may have a band gap energy of about 4.0 eV or more and about 6.0 eV or less, and may have a dielectric constant of about 10 or more. The oxide layer 170 may be formed in a uniform thickness on the dielectric structure 160.

Referring to FIG. 4I, the upper electrode UE may be formed on the resulting structure of FIG. 4H to manufacture the semiconductor memory device 10 illustrated in FIG. 2. In example embodiments, for example, a CVD, MOCVD, PVD, or ALD process may be used to form the upper electrode UE.

FIGS. 5A and 5B are graphs for explaining effects of the semiconductor memory device according to an embodiment. For convenience of description, FIGS. 3A and 3F will be referred to together when describing FIGS. 5A and 5B. In FIGS. 5A and 5B, a horizontal axis represents the intensity of the electric field E, and a vertical axis represents the intensity of the polarization P.

For example, the graph shown in FIG. 5A shows the intensity of the polarization P according to the intensity of the electric field E applied to the capacitor CPa shown in FIG. 3A. In an embodiment, the oxide layer 170 including a high dielectric material may be disposed between the upper electrode UE and the dielectric structure 160a, and the metal oxide layer 180 may be disposed between the lower electrode LE and the dielectric structure 160a. In this case, when the metal oxide layer 180 having a higher conductivity than the oxide, etc. is disposed between the lower electrode LE and the dielectric structure 160a, polarization may be generated in the dielectric structure 160a even when a lower positive voltage is applied to the upper and lower electrodes UE and LE. On the other hand, when the oxide layer 170 including a high dielectric material is disposed between the upper electrode UE and the dielectric structure 160a, polarization may be generated in the dielectric structure 160a when a higher negative voltage is applied to the upper and lower electrodes UE and LE. Thus, the graph of the polarization P according to the intensity of the electric field E of the capacitor including a general anti-ferroelectric may be shifted to the left.

For example, the graph shown in FIG. 5B shows the intensity of the polarization P according to the intensity of the electric field E applied to the capacitor CPf shown in FIG. 3F. In an embodiment, the oxide layer 170 including a high dielectric material may be disposed between the lower electrode LE and the dielectric structure 160f, and the metal oxide layer 180 may be disposed between the upper electrode UE and the dielectric structure 160f. In this case, when the metal oxide layer 180 having a higher conductivity than the oxide, etc. is disposed between the upper electrode UE and the dielectric structure 160f, polarization may be generated in the dielectric structure 160f even when a lower positive voltage is applied to the upper and lower electrodes UE and LE. On the other hand, when the oxide layer 170 including a high dielectric material is disposed between the lower electrode LE and the dielectric structure 160f, polarization may be generated in the dielectric structure 160f when a higher negative voltage is applied to the upper and lower electrodes UE and LE. Thus, the graph of the polarization P according to the intensity of the electric field E of the capacitor including a general anti-ferroelectric may be shifted to the right, unlike the capacitor CPa of FIG. 3A shown in FIG. 5A.

While the inventive concept has been particularly shown and described with reference to embodiments thereof, it will be understood by those of ordinary skill in the art that various changes in form and detail may be made therein without departing from the spirit and scope of the inventive concept as defined by the following claims.

What is claimed is:

1. A semiconductor memory device, comprising:
an upper electrode;
a lower electrode;
an anti-ferroelectric layer disposed between the upper electrode and the lower electrode and comprising an anti-ferroelectric;
an oxide layer disposed on a first surface of the anti-ferroelectric layer and comprising a high dielectric material; and
a metal oxide layer disposed on a second surface of the anti-ferroelectric layer opposite to the first surface,
wherein a thickness of each of the oxide layer and the metal oxide layer is less than a thickness of the anti-ferroelectric layer.

2. The semiconductor memory device of claim 1, further comprising:
a ferroelectric layer disposed between the anti-ferroelectric layer and the oxide layer or between the anti-ferroelectric layer and the metal oxide layer, wherein the ferroelectric layer comprises a ferroelectric.

3. The semiconductor memory device of claim 2, wherein the thickness of the anti-ferroelectric layer is greater than a thickness of the ferroelectric layer.

4. The semiconductor memory device of claim 1, wherein
the oxide layer is in contact with the first surface of the anti-ferroelectric layer, and
the metal oxide layer is in contact with the second surface of the anti-ferroelectric layer.

5. The semiconductor memory device of claim 1, wherein the anti-ferroelectric comprises at least one of ZrO₂, PbZrO₃, AgNbO₃, or HfₓZr₁₋ₓ O₂, wherein x is a positive number smaller than about 0.5.

6. The semiconductor memory device of claim 1, wherein a vertical distance between the oxide layer and the metal oxide layer is about 5 Å or more and less than about 100 Å.

7. The semiconductor memory device of claim 1, wherein the high dielectric material comprises at least one of La₂O₃, Y₂O₃, Ta₂O₅, SrO, or Ga₂O₃.

8. The semiconductor memory device of claim 1, wherein the metal oxide layer comprises at least one of Ta₊₅, W₊₆, Nb₊₅, Mo₊₆, In₊₃, Zn₊₂, Ga₊₃, or Ni₊₂.

9. The semiconductor memory device of claim 1, wherein
the high dielectric material has a bandgap energy of about 4.0 eV or more and about 6.0 eV or less, and
has a dielectric constant of about 10 or more.

10. The semiconductor memory device of claim 1, wherein
the upper electrode is in contact with the oxide layer,
the lower electrode is in contact with the metal oxide layer, and
the anti-ferroelectric layer is in contact with at least one of the oxide layer or the metal oxide layer.

11. A semiconductor memory device, comprising:
an upper electrode;
a lower electrode;
a dielectric structure disposed between the upper electrode and the lower electrode;
an oxide layer disposed between the lower electrode and the dielectric structure and comprising a high dielectric material; and
a metal oxide layer disposed between the upper electrode and the dielectric structure and comprising a metal material, wherein
the dielectric structure comprises at least one anti-ferroelectric layer comprising an anti-ferroelectric,
a thickness of each of the oxide layer and the metal oxide layer in a direction orthogonal to an upper surface of the upper electrode is less than a thickness of the dielectric structure, and
the oxide layer is in contact with the lower electrode, and the metal oxide layer is in contact with the upper electrode.

12. The semiconductor memory device of claim 11, wherein
the at least one anti-ferroelectric layer is one of a plurality of anti-ferroelectric layers,
the dielectric structure further comprises a plurality of ferroelectric layers comprising a plurality of ferroelectrics, and
the anti-ferroelectric layer and the ferroelectric layer are alternately laminated between the oxide layer and the metal oxide layer.

13. The semiconductor memory device of claim 12, wherein a ferroelectric layer disposed closest to the oxide layer among the plurality of ferroelectric layers is disposed closer to the oxide layer than an anti-ferroelectric layer that is disposed closest to the oxide layer among the plurality of anti-ferroelectric layers.

14. The semiconductor memory device of claim 11, wherein the anti-ferroelectric comprises at least one of ZrO₂, PbZrO₃, AgNbO₃, or HfₓZr₁₋ₓO₂, wherein x is a positive number smaller than 0.5.

15. The semiconductor memory device of claim 12, wherein
thicknesses of the plurality of anti-ferroelectric layers are different from each other, and
thicknesses of the plurality of ferroelectric layers are different from each other.

16. The semiconductor memory device of claim 11, wherein a thickness of the at least one anti-ferroelectric layer is about 5 Å or more and about 95 Å or less.

17. The semiconductor memory device of claim 11, wherein the high dielectric material comprises at least one of La₂O₃, Y₂O₃, Ta₂O₅, SrO, or Ga₂O₃.

18. The semiconductor memory device of claim 11, wherein the metal material comprises at least one of Ta⁺⁵, W⁺⁶, Nb⁺⁵, Mo⁺⁶, In⁺³, Zn⁺², Ga⁺³, or Ni⁺².

19. A semiconductor memory device, comprising:
a substrate;
an active region defined by a device separation layer formed on the substrate;
a word line crossing the active region and extending in a first direction on the substrate;
a bit line extending in a second direction orthogonal to the first direction on the substrate; and
a capacitor disposed at a higher level than the bit line, wherein
the capacitor comprises:
at least one anti-ferroelectric layer comprising an upper electrode, a lower electrode, and an anti-ferroelectric disposed between the upper electrode and the lower electrode;
an oxide layer disposed between the upper electrode and the anti-ferroelectric layer and comprising a high dielectric material; and
a metal oxide layer disposed between the lower electrode and the anti-ferroelectric layer and comprising a metal material,
wherein a thickness of each of the oxide layer and the metal oxide layer is less than a thickness of the at least one anti-ferroelectric layer.

20. The semiconductor memory device of claim 19, further comprising:
a plurality of ferroelectric layers comprising ferroelectrics,
wherein the at least one anti-ferroelectric layer is one of a plurality of anti-ferroelectric layers, and
the anti-ferroelectric layers and the ferroelectric layers are alternately laminated between the oxide layer and the metal oxide layer.
